(19) United States
(12) Patent Application Publication
(10) Pub. No.: US 2017/0271286 A1
(43) Pub. Date: Sep. 21, 2017

(54) SEMICONDUCTOR DEVICE CAPABLE OF DISPERSING STRESSES

(71) Applicant: SAMSUNG ELECTRONICS CO., LTD., SUWON-SI (KR)

(72) Inventor: YOUNGBAE KIM, Seoul (KR)

(21) Appl. No.: 15/407,422

(22) Filed: Jan. 17, 2017

(30) Foreign Application Priority Data
Mar. 16, 2016 (KR) 10-2016-0031631

(51) Int. Cl. H01L 23/00

(52) U.S. Cl. CPC H01L 24/05; H01L 2224/0401; H01L 2924/35; H01L 2224/02125; H01L 2224/05095; H01L 2224/05097; H01L 2224/05092; H01L 2224/05088; H01L 2224/05086

(57) ABSTRACT

A semiconductor device includes a semiconductor substrate including a circuit layer disposed therein, a bonding pad disposed on the semiconductor substrate, the bonding pad being electrically connected to the circuit layer, and a metal layer electrically connected to the bonding pad. The metal layer includes a first via electrically connected to the bonding pad, the first via providing an electrical path between the metal layer and the circuit layer, and a second via protruding toward the semiconductor substrate, the second via supporting the metal layer on the semiconductor substrate.

### CROSS-REFERENCE TO RELATED APPLICATIONS

This U.S. nonprovisional patent application claims priority under 35 U.S.C. §119 to Korean Patent Application 10-2016-0031631, filed on Mar. 16, 2016, in the Korean Intellectual Property Office, the disclosure of which is incorporated by reference herein in its entirety.

### TECHNICAL FIELD

The present inventive concept relates to a semiconductor device and, more particularly, to a semiconductor device capable of dispersing stresses.

### DISCUSSION OF THE RELATED ART

Generally, a semiconductor device may be formed by stacking a plurality of layers on a substrate. Each of the plurality of layers may have different coefficients of thermal expansion (CTEs). Since the plurality of layers may have different CTEs, the heating or cooling of the semiconductor device may cause the plurality of layers to expand or contract by different amounts (e.g., unevenly) with respect to each other. Thus, the heating or cooling of the semiconductor device may subject the plurality of layers to longitudinal and/or shear stress. The longitudinal and/or shear stress may cause one or more of the plurality of layers to crack.

### SUMMARY

Exemplary embodiments of the present inventive concept relate to a semiconductor device that may have reduced stresses between elements of the semiconductor device.

According to an exemplary embodiment of the present inventive concept, a semiconductor device includes a semiconductor substrate including a circuit layer disposed therein, a bonding pad disposed on the semiconductor substrate, the bonding pad being electrically connected to the circuit layer, and a metal layer electrically connected to the bonding pad. The metal layer includes a first via electrically connected to the bonding pad, the first via providing an electrical path between the metal layer and the circuit layer, and a second via protruding toward the semiconductor substrate, the second via supporting the metal layer on the semiconductor substrate.

According to an exemplary embodiment of the present inventive concept, a semiconductor device includes a semiconductor chip mounted on a package substrate, and an interconnection terminal disposed between the package substrate and the semiconductor chip, the interconnection terminal electrically connecting the semiconductor chip to the package substrate. The semiconductor chip includes a semiconductor substrate including a circuit layer therein, a bonding pad disposed on the semiconductor substrate, the boding pad being electrically connected to the circuit layer, and a first metal layer electrically connected to the bonding pad. The first metal layer includes a signal via connected to the bonding pad and forming an electrical path between the bonding pad and the interconnection terminal, and a dummy via protruding from the first metal layer toward the semiconductor substrate, the dummy via supporting the first metal layer.

According to an exemplary embodiment of the present inventive concept, a semiconductor device includes a package substrate, a semiconductor chip, and an interconnection terminal disposed between the package substrate and the semiconductor chip. The semiconductor chip includes a semiconductor substrate, bonding pad disposed on the semiconductor substrate, and a metal layer disposed on the bonding pad, wherein the metal layer is electrically connected to the bonding pad and to the interconnection terminal. The interconnection terminal, the bonding pad and the metal layer electrically connect the package substrate to the semiconductor chip. The metal layer includes a first protrusion and a second protrusion. The first protrusion is electrically connected to the bonding pad.

### BRIEF DESCRIPTION OF THE DRAWINGS

The above and other features of the present inventive concept will become more apparent by describing in detail exemplary embodiments thereof in conjunction with the accompanying drawings, in which:

FIG. 1 is a cross-sectional view illustrating a semiconductor device according to an exemplary embodiment of the present inventive concept;

FIG. 2A is a cross-sectional view illustrating a portion of a semiconductor device according to an exemplary embodiment of the present inventive concept;

FIG. 2B is a cross-sectional view illustrating a portion of a semiconductor device according to an exemplary embodiment of the present inventive concept; and

FIGS. 3A to 3G are plan views taken along line A-A of FIG. 2A or along line A-A of FIG. 2B, according to exemplary embodiments of the present inventive concept.

### DETAILED DESCRIPTION OF EMBODIMENTS

Exemplary embodiments of the present inventive concept will now be described more fully hereinafter with reference to the accompanying drawings. The present inventive concept may, however, be embodied in different forms and should not be construed as limited to the embodiments set forth herein. The layers and/or elements in the drawings may be exaggerated for clarity.

When a layer or element is referred to as being provided/disposed on another layer or element, the layer or element may be directly provided/disposed on the other layer or element, or intervening layers or elements may be present therebetween. Like reference numerals may refer to like elements throughout the specification.

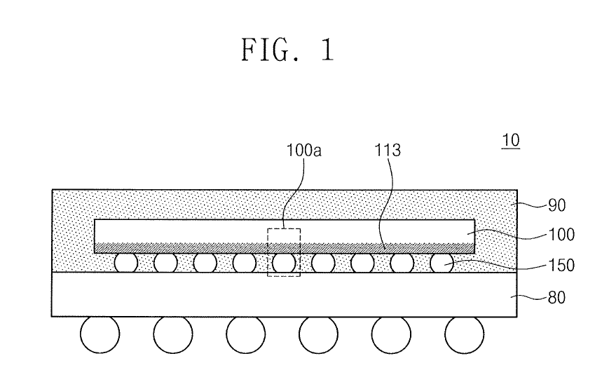

FIG. 1 is a cross-sectional view illustrating a semiconductor device according to an exemplary embodiment of the present inventive concept.

Referring to FIG. 1, the semiconductor device may include a semiconductor package 10. The semiconductor package 10 may include a package substrate 80, a semiconductor chip 100 mounted on the package substrate 80, and a mold layer 90 encapsulating the semiconductor chip 100. The semiconductor chip 100 may be mounted on the package substrate 80 in a flip chip bonding manner in which a circuit layer 113 including an integrated circuit, may face the package substrate 80. The package substrate 80 may be a printed circuit board (PCB). The circuit layer 113 may include a memory circuit, a logic circuit, or a combination thereof. One or more interconnection terminals 150 may be disposed between the semiconductor chip 100 and the package substrate 80. The interconnection terminals 150 may include solder bumps, solder balls, or the like. The mold layer 90 may include an epoxy molding compound (EMC).

The semiconductor package 10 may further include at least one electrical connection structure 100a that may electrically connect the semiconductor chip 100 to the package substrate 80. In an exemplary embodiment of the present inventive concept, the electrical connection structure 100a may have a structure configured to disperse mechanical and/or thermal stresses applied to the semiconductor chip 100 by the interconnection terminals 150.

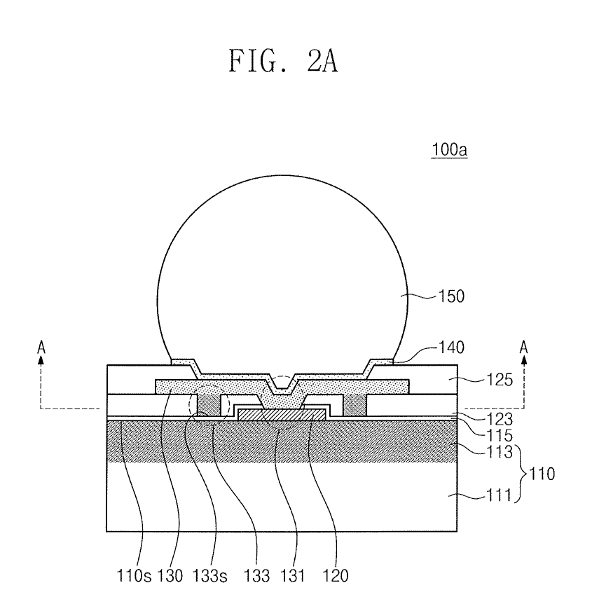

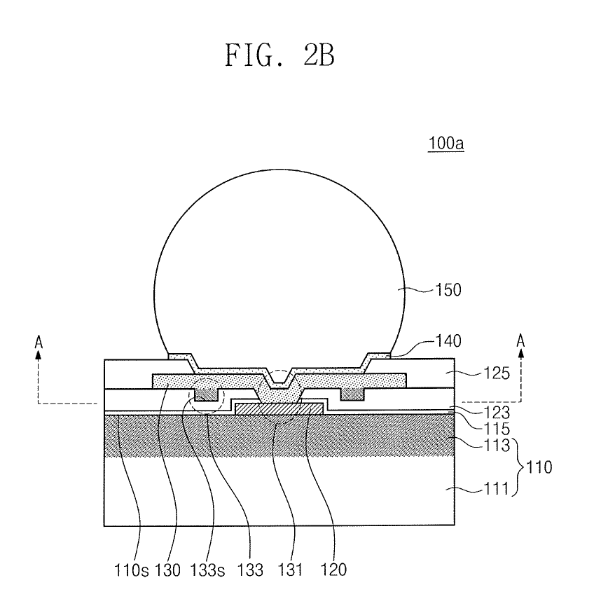

FIG. 2A is a cross-sectional view illustrating a portion of a semiconductor device according to an exemplary embodiment of the present inventive concept. FIG. 2B is a cross-sectional view illustrating a portion of a semiconductor device according to an exemplary embodiment of the present inventive concept.

Referring to FIGS. 1 and 2A, the semiconductor chip 100 may include a semiconductor substrate 110, a bonding pad 120 disposed on the semiconductor substrate 110, and a first metal layer 130 disposed on the semiconductor substrate 110. The semiconductor substrate 110 may include the circuit layer 113 and a silicon wafer 111. The circuit layer 113 may be disposed on the silicon wafer 111. The bonding pad 120 may be electrically connected to the circuit layer 113. The first metal layer 130 may be electrically connected to the bonding pad 120. The semiconductor chip 100 may further include a second metal layer 140 such as an under bump metal (UBM) disposed between the first metal layer 130 and the interconnection terminal 150. The first metal layer 130 may be a redistribution layer, but exemplary embodiments of the present inventive concept are not limited thereto. The semiconductor chip 100 may further include an insulation layer 115 that covers the semiconductor substrate 110, a first protection layer 123 disposed on the insulation layer 115, and a second protection layer 125 disposed on the first protection layer 123. The bonding pad 120 may be formed on the insulation layer 115. The insulation layer 115 may partially expose the bonding pad 120. The insulation layer 115, the first protection layer 123, and/or the second protection layer 125 may include an insulating inorganic layer (e.g., a silicon oxide layer and/or a silicon nitride layer) or an insulating organic layer (e.g., a polyimide layer). For example, the insulation layer 115 may include a silicon oxide layer, and the first and second protection layers 123 and 125 may include a polyimide layer.

The electrical connection structure 100a may include the interconnection terminal 150 electrically connected to the package substrate 80, and the first metal layer 130 electrically connected to the bonding pad 120. The electrical connection structure 100a may further include the second metal layer 140 disposed between the first metal layer 130 and the interconnection terminal 150. In an exemplary embodiment of the present inventive concept, the first metal layer 130 may be disposed on the first protection layer 123, and the first metal layer 130 may horizontally extend along a top surface 110s of the semiconductor substrate 110. For example, the first metal layer 130 may extend substantially parallel to the top surface 110s. The top surface 110s of the semiconductor substrate 110 may be an active surface. A portion of the first metal layer 130 may be included in a first via 131. The first via 131 may extend downward toward the semiconductor substrate 110 to penetrate the first protection layer 123 and the insulation layer 115. The first via 131 may be connected to the bonding pad 120. Second vias 133 may be respectively formed by protruding portions of the first metal layer 130. The portions of the first metal layer 130 that form the second vias 133 may protrude downward toward the semiconductor substrate 110 to penetrate the first protection layer 123. For example, the portions of the first metal layer 130 that form the second vias 133 may protrude perpendicularly to a surface of the first metal layer 130. The second vias 133 may be disposed on the insulation layer 115. The second vias 133 may be portions of the first metal layer 130, not metallic patterns formed separately from the first metal layer 130. The second vias 133 may have a bottom surface 133s in contact with the insulation layer 115. Alternatively, as shown in FIG. 2B, the second vias 133 may partially penetrate the first protection layer 123, and the bottom surface 133s of the second via 133 might not be in contact with the insulation layer 115.

The first vias 131 may serve as signal vias, each of which providing electrical paths between the semiconductor chip 100 and the package substrate 80. The second vias 133 may serve as support or dummy vias that disperse mechanical and/or thermal stresses which the semiconductor chip 100 may be subjected to by the interconnection terminals 150. The second vias 133 might not be electrically conductive. The second vias 133 might not be in direct contact with the semiconductor substrate 110 or the bonding pad 120.

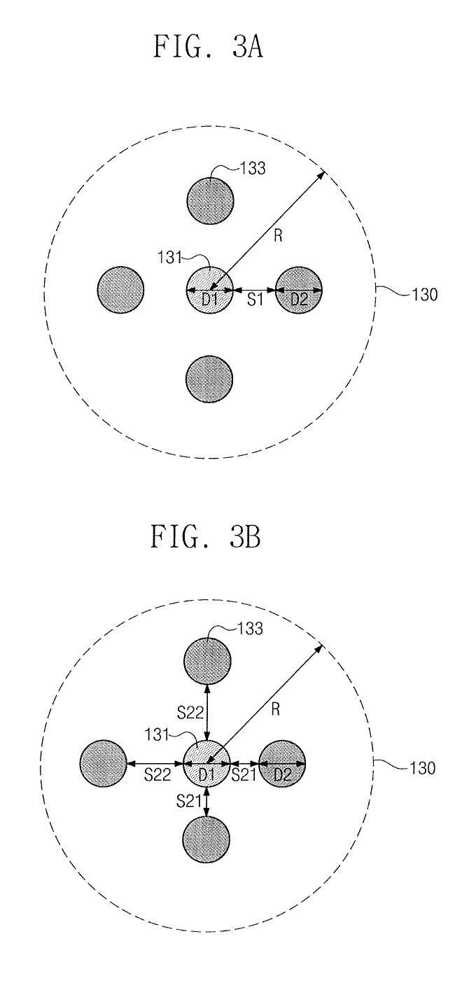

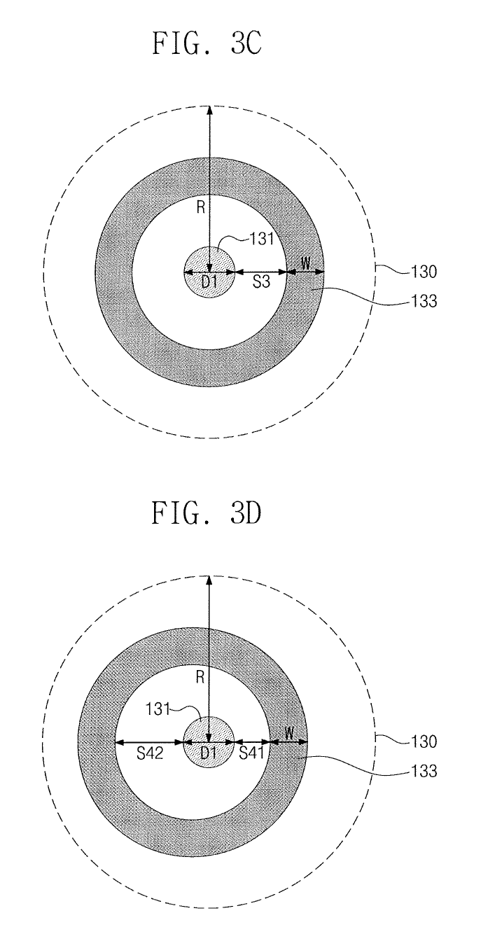

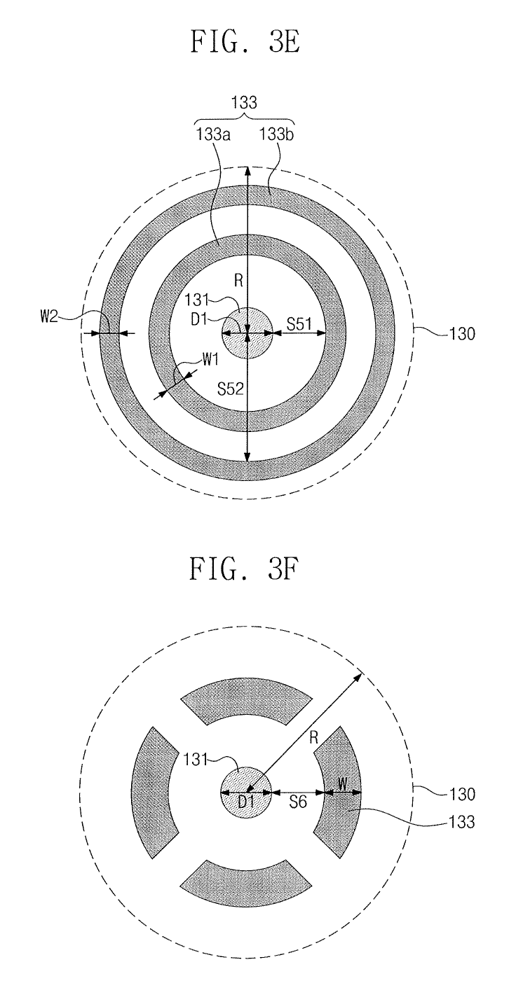

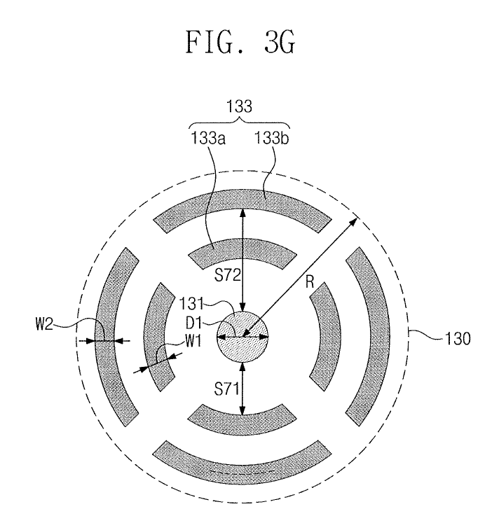

Various layers included in the semiconductor chip 100 may have different coefficients of thermal expansion (CTEs). For example, the silicon wafer 111, the circuit layer 113, and the protection layers 123 and 125 may have different CTEs from one another. Also, the semiconductor chip 100 and the package substrate 80 may have different CTEs from one another. The different CTEs may cause the semiconductor chip 100 to be subjected to mechanical and/or thermal stresses. For example, when stress is transferred to the semiconductor chip 100 from the package substrate 80, or vice versa, through the interconnection terminals 150, the stress may be concentrated on the first via 131. The concentrated stress may generate a crack between the first metal layer 130 and the bonding pad 120. The crack between the first metal layer 130 and the bonding pad 120 may prevent a good electrical connection between the first metal layer 130 and the bonding pad 120. Thus, the crack between the first metal layer 130 and the bonding pad 120 may cause an electrical failure of the semiconductor chip 100 and/or the semiconductor package 10. In an exemplary embodiment of the present inventive concept, the second vias 133 of the first metal layer 130 may disperse mechanical and/or thermal stresses to which the semiconductor substrate 110 is exposed. Accordingly, the occurrence of cracks generated by the stress concentration on the first vias 131 may be eliminated or reduced. One or more second vias 133 may be disposed in each electrical connection structure 100a. The vias 133 may be variously arranged, as described below with reference to FIGS. 3A to 3G.

FIGS. 3A to 3G are plan views taken along line A-A of FIG. 2A or along line A-A of FIG. 2B, according to exemplary embodiments of the present inventive concept.

Referring to FIG. 3A, a plurality of pillar shaped second vias 133 may be arranged to surround the first via 131. For example, the second vias 133 may be arranged in a shape of a polygon (e.g., a rhombus) or ring around the first via 131. The second vias 133 may be equally spaced apart from the first via 131. The second vias 133 may be arranged to be equally spaced apart from each other at the same intervals along a circular direction. The first metal layer 130 may have a circular shape, in plan view. In addition, the first and second vias 131 and 133 may have a circular shape in plan view. The first via 131 may be positioned at a central point of the first metal layer 130 in FIGS. 3A to 3G, unless otherwise noted. An interval S1 between the first via 131 and a second via 133 may be substantially the same as or greater than a diameter D1 of the first via 131. For example, the interval S1 may exist (e.g., be disposed) between an outer circumference of the first via 131 and the inside of the first metal layer 130, the first metal layer 130 having a diameter 2R. For example, D1<S1<2R. The second vias 133 may each have a diameter D2 equal to or substantially equal to the diameter D1 of the first via 131. Alternatively, the diameter D2 of the second vias 133 may be greater than or smaller than the diameter D1 of the first via 131. The interval S1 may be a linear distance between the first via 131 and the second via 133.

Referring to FIG. 3B, in an exemplary embodiment of the present inventive concept, the second vias 133 might not be equally spaced apart from the first via 131. For example, at least one of the second vias 133 may be spaced apart from the first via 131 by a first interval S21, and at least another one of the second vias 133 may be spaced apart from the first via 131 by a second interval S22 greater than the first interval S21. At least one of the first and second intervals S21 and S22 may be substantially the same as or greater than the diameter D1 of the first via 131. For example, the first interval S21 may exist (e.g., be disposed) between an outer circumference of the first via 131 and the inside of the first metal layer 130, the first metal layer 130 having a diameter 2R. For example, D1<S21<2R.

Referring to FIG. 3C, the second via 133 may have a ring shape (e.g., a curved shape) that continuously encloses the first via 131 on a plan view. The second via 133 may have a width W equal to or different from the diameter D1 of the first via 131. An interval S3 between the first via 131 and the second via 133 may be substantially the same as or greater than the diameter D1 of the first via 131. For example, the interval S3 may exist, (e.g., be disposed) between the outer circumference of the first via 131 and the inside of the first metal layer 130, the first metal layer 130 having a diameter 2R. For example, D1<S3<2R. For example, a central point of the first via 131 may be positioned on a central point of the second via 133.

Referring to FIG. 3D, in an exemplary embodiment of the present inventive concept, a central point of the first via 131 may be positioned at a location different from a location of the central point of the second via 133. For example, the first via 131 may be spaced apart from one inner side of the second via 133 at a first interval S41 and spaced apart from an opposite inner side of the second via 133 at a second interval S42 greater than the first interval S41. The first and/or second intervals S41 and S42 may be substantially the same as or greater than the diameter D1 of the first via 131. For example, the first interval S41 may exist (e.g., be disposed between outer circumference of the first via 131 and the inside of the first metal layer 130, the first metal layer 130 having a diameter 2R. For example, D1<S41<2R.

Referring to FIG. 3E, in an exemplary embodiment of the present inventive concept, the first via 131 may be surrounded by a plurality of ring shaped second vias 133. The second vias 133 may include an inner ring shaped via 133a surrounding the first via 131 and an outer ring shaped via 133b surrounding the inner ring-shaped via 133a. One or more additional ring shaped vias may be further disposed between the inner and outer ring shaped vias 133a and 133b. The inner ring shaped via 133a may have a first width W1 and spaced apart from the first via 131 by a first interval S51. The outer ring shaped via 133b may have a second width W2 and spaced apart from the first via 131 at a second interval S52 greater than the first interval S51. The first width W1 may be substantially the same as or different from the second width W2. The diameter D1 of the first via 131 may be substantially the same as or different from the first width W1 and/or the second width W2. The first and/or second intervals S51 and S52 may be substantially the same as or greater than the diameter D1 of the first via 131. For example, the first interval S51 may exist, (e.g., be disposed) between the outer circumference of the first via 131 and the inside of the first metal layer 130, the first metal layer 130 having a diameter 2R. For example, D1<S51<2R. Each of the inner and outer ring shaped vias 133a and 133b may have a central point positioned to correspond a central point of the first via 131. For example, the inner and outer ring-shaped vias 133a and 133b may be concentric rings. Alternatively, similarly to FIG. 3D, at least one of the inner and outer ring-shaped vias 133a and 133b may have a central point positioned at a different location from a location of a central point of the first via 131 (e.g., not concentric rings).

Referring to FIG. 3F, a plurality of arc shaped second vias 133 may be arranged in a ring (e.g., circle) around the first via 131. The second vias 133 may be equally spaced apart from the first via 131. The second vias 133 may be equally spaced apart from each other along a circular direction and discontinuously (e.g., partially) surround the first via 131. Each of the second vias 133 may have a width W substantially the same as or different from the diameter D1 of the first via 131. An interval S6 between the first via 131 and the second vias 133 may be substantially the same as or greater than the diameter D1 of the first via 131. For example, the interval S6 may exist (e.g., be disposed) between the outer circumference of the first via 131 and the inside of the first metal layer 130, the first metal layer 130 having a diameter 2R. For example, D1<S6<2R. Alternatively, similarly to FIG. 3D, one of the second vias 133 may be positioned closer the first via 131 than the other second vias 133.

Referring to FIG. 3G, a plurality of arc shaped second vias 133 may be arranged in a double ring around the first via 131. The second vias 133 may include a plurality of inner arc shaped vias 133a, each with a first width W1, that surround the first via 131. In addition, the second vias 133 may include a plurality of outer arc shaped vias 133b, each with a second width W2, that surround the inner arc shaped vias 133a. The inner arc shaped vias 133a may be equally spaced apart from each other along a circular direction and equally spaced apart from the first via 131 by a first interval S71. The outer arc shaped vias 133b may be equally spaced apart from each other along a circular direction and equally spaced apart from the first via 131 by a second interval S72 greater than the first interval S71. The first width W1 may be substantially the same as or different from the second width W2. The diameter D1 of the first via 131 may be substantially the same as or different from the first width W1 and/or the second width W2.

At least one of the first interval S71 and the second interval S72 may be substantially the same as or greater than the diameter D1 of the first via 131. For example, the first interval S71 may exist (e.g., be disposed) between the outer circumference of the first via 131 and the inside of the first metal layer 130, the first metal layer 130 having a diameter 2R. For example, D1<S71<2R.

Alternatively, similarly to FIG. 3D, one of the inner arc shaped vias 133a may be positioned closer the first via 131 than the other arc-shaped vias 133a. In addition, one of the outer arc shaped vias 133b may be positioned closer to the first via 131 than the other outer arc shaped vias 133b.

According to exemplary embodiments of the present inventive concept, the metal layer connected to the bonding pad includes at least one support via such that the support via may disperse or relieve stress applied to the metal layer. Accordingly, the semiconductor device which includes the semiconductor package may have good electrical contact reliability between the metal layer and the bonding pad. In addition, the semiconductor device which includes the semiconductor package may have increased durability to stress.

While the present inventive concept has been particularly shown and described with reference to exemplary embodiments thereof, it will be apparent to those of ordinary skill in the art that various changes in form and detail may be made therein without departing from the spirit and scope of the present inventive concept.

What is claimed is:

1. A semiconductor device, comprising:
a semiconductor substrate including a circuit layer disposed therein;
a bonding pad disposed on the semiconductor substrate, the bonding pad being electrically connected to the circuit layer; and
a metal layer electrically connected to the bonding pad,
wherein the metal layer comprises:
a first via electrically connected to the bonding pad, the first via providing an electrical path between the metal layer and the circuit layer; and
a second via protruding toward the semiconductor substrate, the second via supporting the metal layer on the semiconductor substrate.

2. The semiconductor device of claim 1, further comprising:
an insulation layer disposed on the semiconductor substrate, the insulation layer covering the bonding pad; and
a protection layer disposed on the insulation layer,
wherein the metal layer is disposed on the protection layer,
wherein the first via extends toward the bonding pad and contacts the bonding pad, and
wherein the second via is disposed on the insulation layer.

3. The semiconductor device of claim 2, wherein the first via penetrates the protection layer and the insulation layer to be in contact with the bonding pad, and the second via penetrates the protection layer to be in contact with the insulation layer.

4. The semiconductor device of claim 2, wherein the first via penetrates the protection layer and the insulation layer to be in contact with the bonding pad, and the second via partially penetrates the protection layer, the second via not being in contact with the insulation layer.

5. The semiconductor device of claim 1, wherein the second via comprises one or more metal pillars that are spaced apart from the first via.

6. The semiconductor device of claim 5, wherein the one or more metal pillars are arranged in a circle around the first via in plan view.

7. The semiconductor device of claim 6, wherein the one or more metal pillars are spaced apart equally from the first via.

8. The semiconductor device of claim 5, wherein the one or more metal pillars are spaced apart equally from each other and disposed in a circle.

9. The semiconductor device of claim 1, wherein the second via comprises at least one ring-shaped via circumscribing the first via.

10. The semiconductor device of claim 1, wherein the second via comprises a plurality of arc-shaped vias spaced apart from each other, the plurality of arc-shaped vias surrounding the first via.

11. A semiconductor device, comprising:
a semiconductor chip mounted on a package substrate; and
an interconnection terminal disposed between the package substrate and the semiconductor chip, the interconnection terminal electrically connecting the semiconductor chip to the package substrate,
wherein the semiconductor chip comprises:
a semiconductor substrate including a circuit layer therein;
a bonding pad disposed on the semiconductor substrate, the boding pad being electrically connected to the circuit layer; and
a first metal layer electrically connected to the bonding pad,
wherein the first metal layer comprises:
a signal via connected to the bonding pad and forming an electrical path between the bonding pad and the interconnection terminal; and
a dummy via protruding from the first metal layer toward the semiconductor substrate, the dummy via supporting the first metal layer.

12. The semiconductor device of claim 11, wherein the signal via and the dummy via have a circular shape in plan view.

13. The semiconductor device of claim 12, wherein the dummy via comprises one or more metal pillars circularly arranged around the first via, the one or more metal pillars being spaced apart equally from each other.

14. The semiconductor device of claim 13, wherein at least one of the one or more metal pillars is separated from the signal via by a distance that is equal to or greater than a diameter of the signal via.

15. The semiconductor device of claim 11, wherein the signal via has a circular shape in plan view, and the one or more dummy vias have a ring shape or an arc shape surrounding the signal via in plan view.

16. A semiconductor device, comprising:
a package substrate;
a semiconductor chip; and
an interconnection terminal disposed between the package substrate and the semiconductor chip,
wherein the semiconductor chip includes:
a semiconductor substrate;
a bonding pad disposed on the semiconductor substrate; and
a metal layer disposed on the bonding pad, wherein the metal layer is electrically connected to the bonding pad and to the interconnection terminal,
wherein the interconnection terminal, the bonding pad and the metal layer electrically connect the package substrate to the semiconductor chip,
wherein the metal layer includes a first protrusion and a second protrusion, and
wherein the first protrusion is electrically connected to the bonding pad.

17. The semiconductor device of claim 16, wherein the first protrusion passes through at least one protection layer disposed between the bonding pad and the metal layer.

18. The semiconductor device of claim 16, further comprising:
a first protection layer disposed between the metal layer and the bonding pad, wherein the first protrusion protrudes through the first protection layer in a direction toward the bonding pad, and wherein the second protrusion penetrates the first protection layer at least partially in a direction toward the semiconductor substrate.

19. The semiconductor device of claim 18, wherein the metal layer includes a plurality of second protrusions, wherein the first protrusion is disposed between the plurality of second protrusions.

20. The semiconductor device of claim 18, wherein either the second protrusion is curved and surrounds the first protrusion, or the second protrusion has an arc shape.
